(19) United States
(12) Patent Application Publication
(10) Pub. No.: US 2022/0319832 A1
(43) Pub. Date: Oct. 6, 2022

(54) METHOD AND SYSTEM FOR DEPOSITING SILICON NITRIDE WITH INTERMEDIATE TREATMENT PROCESS

(71) Applicant: ASM IP Holding B.V., Almere (NL)

(72) Inventor: Toshiaki Iijima, Tokyo (JP)

(21) Appl. No.: 17/705,206

(22) Filed: Mar. 25, 2022

Related U.S. Application Data
(60) Provisional application No. 63/167,786, filed on Mar. 30, 2021.

(51) Int. Cl. H01L 21/02; C23C 16/455; C23C 16/34; H01L 21/311

(52) U.S. Cl. CPC H01L 21/0228; H01L 21/02274; H01L 21/0217; H01L 21/02211; C23C 16/45553; C23C 16/45536; C23C 16/345; H01L 21/31111

(57) ABSTRACT

Methods of depositing silicon nitride on a surface of a substrate are disclosed. The methods include using an intermediate treatment process to increase a quality of the silicon nitride layer and a second treatment process.

### CROSS-REFERENCE TO RELATED APPLICATIONS

This application claims the benefit of U.S. Provisional Application No. 63/167,786, filed on Mar. 30, 2021, in the United States Patent and Trademark Office, the disclosure of which is incorporated herein in its entirety by reference.

### FIELD OF INVENTION

The present disclosure generally relates to methods and systems for forming structures suitable for forming electronic devices. More particularly, examples of the disclosure relate to methods and systems for forming layers comprising silicon nitride.

### BACKGROUND OF THE DISCLOSURE

During the formation of electronic devices, such as semiconductor devices, it may be desirable to deposit silicon nitride layers overlying high aspect ratio features. Atomic layer deposition (ALD) can be used to conformally deposit silicon nitride overlying such features.

In some cases, a plasma-enhanced process, such as plasma-enhanced ALD (PEALD), can be used to deposit silicon nitride. Plasma-enhanced processes can be operated at relatively low temperatures and/or exhibit relatively high deposition rates, compared to methods that do not employ a plasma.

Unfortunately, silicon nitride deposited using PEALD on high aspect-ratio features (e.g., gaps having an aspect ratio of three or more) can exhibit relatively high variation in film quality. For example, a wet etch rate of the silicon nitride along a sidewall of a feature can be relatively high, compared to a wet etch rate of the silicon nitride on the top of the substrate and/or at the top of a feature. Additionally, silicon nitride deposited using PEALD can exhibit relatively poor step coverage overlying high aspect ratio features, which can result in undesirable film thickness variation of the silicon nitride and/or undesirably poor gap-fill of the features.

To overcome such problems, several techniques have been proposed. For example, U.S. Pat. No. 9,887,082 to Pore et al. discloses a method for filling a gap. The method includes providing a precursor into a reaction chamber to form adsorbed species on a surface of a substrate, exposing the adsorbed species to a nitrogen plasma to form species at the top of the feature that include nitrogen, and providing a reactant plasma to the reaction chamber, wherein nitrogen acts as an inhibitor to the reactant, resulting in less material being deposited at the top of the gap, compared to traditional PEALD techniques. Such techniques can result in silicon nitride with fewer voids or seams than traditional techniques, but voids and seams within the silicon nitride can still form, particularly in higher aspect ratio gaps. Further, a wet etch rate of silicon nitride deposited using such techniques can be undesirably high for some applications.

Accordingly, improved methods for depositing silicon nitride on a surface of a substrate and structures formed using such methods are desired. Any discussion of problems and solutions involved in the related art has been included in this disclosure solely for the purposes of providing a context for the present invention and should not be taken as an admission that any or all of the discussion was known at the time the invention was made.

### SUMMARY OF THE DISCLOSURE

Various embodiments of the present disclosure relate to methods of forming silicon nitride layers on a surface of a substrate and to systems for forming the silicon nitride layers. Methods described herein can be used in a variety of applications, including forming of silicon nitride liner layers and/or silicon nitride gap fill processes. While the ways in which various embodiments of the present disclosure address drawbacks of prior methods and systems are discussed in more detail below, in general, various embodiments of the disclosure provide improved methods of forming silicon nitride layers with reduced variation in quality of the layer and/or with improved gap fill.

In accordance with embodiments of the disclosure, a method of depositing a silicon nitride layer is provided. The method can include providing a substrate within a reaction chamber, providing a silicon precursor to the reaction chamber for a silicon precursor pulse period, providing a nitrogen reactant to the reaction chamber for a nitrogen reactant pulse period, providing a deposition plasma power to form a plasma within the reaction chamber for a deposition plasma pulse period, performing an intermediate or first plasma treatment and performing a second plasma treatment. The intermediate plasma treatment can include providing a hydrogen reactant to the reaction chamber for a hydrogen reactant pulse period, wherein the nitrogen reactant pulse period and the hydrogen reactant pulse period overlap for an overlap period, and during the overlap period, providing a first treatment plasma power to the reaction chamber for a first treatment plasma pulse period. The second plasma treatment can include providing a second treatment plasma power to the reaction chamber for a second treatment plasma pulse period, wherein the hydrogen reactant pulse period and the second treatment plasma pulse period do not overlap. In accordance with examples of these embodiments, the deposition plasma power is greater than the second treatment plasma power. In accordance with further examples, the first treatment plasma power is greater than or equal to the second treatment plasma power. As set forth in more detail below, various reactants can be continuously fed to the reaction chamber during one or more deposition cycles, while other reactants are pulsed in a non-continuous manner, to obtain desired treatment and layer properties. Further, flowrates and/or volumetric flow ratios of reactants can be controlled to form silicon nitride with desired properties.

In accordance with yet further exemplary embodiments of the disclosure, a deposition apparatus configured to perform a method as described herein is provided.

In accordance with yet further exemplary embodiments of the disclosure, a structure comprises silicon nitride deposited according to a method described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with at least one embodiment of the disclosure.

FIG. 2 illustrates a timing sequence of a method in accordance with embodiments of the disclosure.

FIG. 3 illustrates structures in accordance with examples of the disclosure.

FIG. 4 illustrates a system in accordance with at least one embodiment of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to methods of depositing a silicon nitride layer onto a surface of a substrate, to deposition apparatus for performing the methods, and to structures formed using the methods. The methods and systems as described herein can be used to process substrates to form, for example, electronic devices. By way of examples, the systems and methods described herein can be used to deposit silicon nitride having relatively uniform film quality (e.g., wet etch rates) overlying high aspect ratio features. Additionally or alternatively, methods and systems described herein can be used to deposit silicon nitride with desired gap fill properties within a recess.

In this disclosure, gas may include material that is a gas at normal temperature and pressure, a vaporized solid and/or a vaporized liquid, and may be constituted by a single gas or a mixture of gases, depending on the context. A gas other than the process gas, e.g., a gas introduced without passing through a gas distribution assembly, such as a showerhead, other gas distribution device, or the like, may be used for, e.g., sealing the reaction space, and may include a seal gas, such as a rare or other inert gas. The term inert gas refers to a gas that does not take part in a chemical reaction to an appreciable extent and/or a gas that can excite a precursor when plasma power is applied. The terms precursor and reactant can be used interchangeably.

As used herein, the term substrate may refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material. Further, the substrate can include various topologies, such as recesses, lines, and the like formed within or on at least a portion of a layer of the substrate. By way of particular examples, a substrate can include features (e.g., protrusions, recesses, or gaps) having an aspect ratio of 3 or more.

In some embodiments, film refers to a layer continuously extending in a direction perpendicular to a thickness direction substantially without pinholes to cover an entire target or concerned surface, or simply a layer covering a target or concerned surface. In some embodiments, layer refers to a structure having a certain thickness formed on a surface or a synonym of film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequences, and/or functions or purposes of the adjacent films or layers.

In this disclosure, continuously can refer to one or more of without breaking a vacuum, without interruption as a timeline, without any material intervening step, without changing treatment conditions, immediately thereafter, as a next step, or without an intervening discrete physical or chemical structure between two structures other than the two structures in some embodiments. For example, a reactant can be supplied continuously during two or more steps and/or cycles of a method.

The term cyclic deposition process or cyclical deposition process can refer to the sequential introduction of precursors (and/or reactants) into a reaction chamber to deposit a layer over a substrate and includes processing techniques, such as atomic layer deposition (ALD), cyclical chemical vapor deposition (cyclical CVD), and hybrid cyclical deposition processes that include an ALD component and a cyclical CVD component.

As used herein, the term atomic layer deposition (ALD) may refer to a vapor deposition process in which deposition cycles, typically a plurality of consecutive deposition cycles, are conducted in a process chamber. Generally, during each cycle, a precursor is introduced and may be chemisorbed to a deposition surface (e.g., a substrate surface or a previously deposited underlying surface, such as material from a previous ALD cycle), forming a monolayer or sub-monolayer that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term atomic layer deposition, as used herein, is also meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of precursor composition(s), reactive gas, and purge (e.g., inert carrier) gas. PEALD refers to an ALD process in which a plasma is applied during one or more of the ALD steps.

As used herein, the term purge may refer to a procedure in which an inert or substantially inert gas is provided to a reactor chamber continuously or in between two pulses of gases which react with each other. For example, a purge may be provided between a precursor pulse and a reactant pulse, thus avoiding or at least reducing gas phase interactions between the precursor and the reactant. It shall be understood that a purge can be effected either in time or in space, or both. For example, in the case of temporal purges, a purge step can be used, e.g., in the temporal sequence of providing a first precursor to a reactor chamber, providing a purge gas to the reactor chamber, and providing a second precursor or a reactant to the reactor chamber, wherein the substrate on which a layer is deposited does not move. In the case of spatial purges, a purge step can take the following form: moving a substrate from a first location to which a first precursor is supplied, through a purge gas curtain, to a second location to which a second precursor is supplied.

As used herein, silicon nitride refers to a material that includes silicon and nitrogen. Silicon nitride can be represented by the formula Si₃N₄. In some cases, the silicon nitride may not include stoichiometric silicon nitride. In some cases, the silicon nitride can include other elements, such as carbon, nitrogen, oxygen, hydrogen, or the like.

As used herein, the term overlap can mean coinciding with respect to time and within a reaction chamber. For example, when two or more reactant pulse periods overlap, there is a period of time in which each of the two reactants is provided to or is present within a reaction chamber.

Further, in this disclosure, any two numbers of a variable can constitute a workable range of the variable as the workable range can be determined based on routine work, and any ranges indicated may include or exclude the endpoints. Additionally, any values of variables indicated (regardless of whether they are indicated with about or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

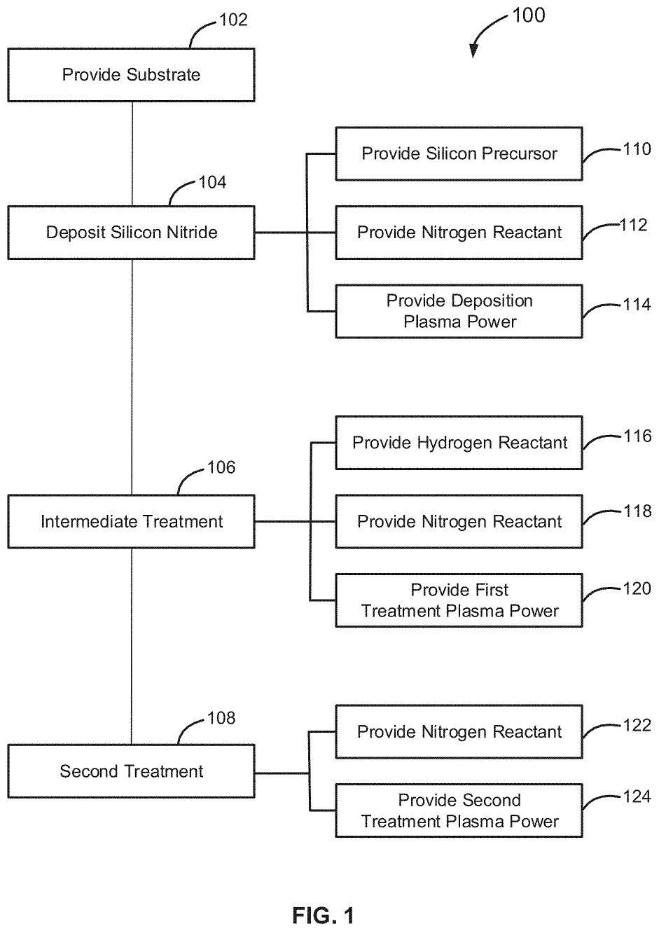

Turning now to the figures, FIG. 1 illustrates a method 100, suitable for depositing a silicon nitride layer in accordance with at least one embodiment of the disclosure. Method 100 includes the steps of providing a substrate within a reaction chamber (step 102), depositing silicon nitride (step 104), performing an intermediate treatment (step 106), and performing a second treatment (step 108). Method 100 and/or various steps thereof can include an a cyclical (e.g., ALD) process, such as a PEALD process.

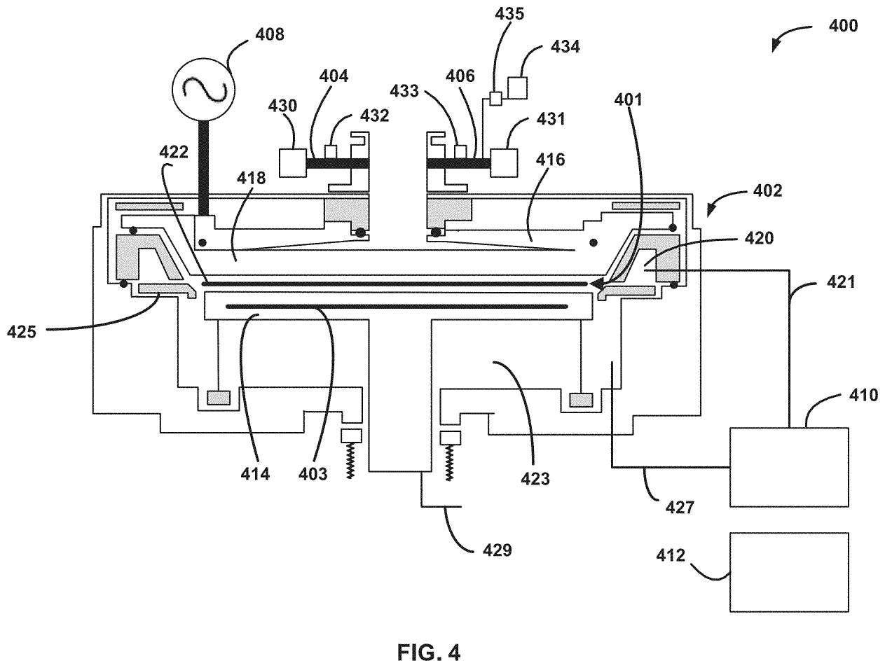

During step 102, a substrate is provided within a reaction chamber of a reactor system. In accordance with examples of the disclosure, the substrate includes a surface comprising patterned features. The patterned features can include recesses, such as trenches, vias, or areas between adjacent protrusions. A reaction chamber used during step 202 can be or include a reaction chamber of a chemical vapor deposition reactor system configured to perform a cyclical deposition process, such as a PEALD process. The reaction chamber can be a standalone reaction chamber or part of a cluster tool. An exemplary suitable reaction chamber is discussed in more detail below in connection with FIG. 4.

Step 102 can include heating the substrate to a desired deposition temperature within the reaction chamber. In some embodiments of the disclosure, step 102 includes heating the substrate to a temperature of less than 800° C. For example, in some embodiments of the disclosure, heating the substrate to a deposition temperature may comprise heating the substrate to a temperature between about 25° C. and about 700° C., about 50° C. and about 600° C., about 100° C. and about 500° C., about 200° C. and about 400° C., or about 300° C. and about 400° C. In addition to controlling the temperature of the substrate, a pressure within the reaction chamber may also be regulated. For example, in some embodiments of the disclosure, the pressure within the reaction chamber during step 102 is between 0.01 Torr and about 50 Torr or about 0.1 Torr and about 30 Torr.

During step 104, a layer of deposited silicon nitride is deposited overlying the substrate provided in step 102. In accordance with examples of the disclosure, step 104 includes a cyclical plasma process, such as a PEALD process or other cyclical process, including formation of active species.

In the illustrated example, step 104 includes providing a silicon precursor to the reaction chamber for a silicon precursor pulse period (substep 110), providing a nitrogen reactant to the reaction chamber for a nitrogen reactant pulse period (substep 112), and providing a deposition plasma power to form a plasma within the reaction chamber for a deposition plasma pulse period to form excited species from the nitrogen reactant to form the layer of deposited silicon nitride (substep 114). The pressure and/or temperature during step 104 can be within the ranges set forth above in connection with step 102.

During substep 110, the silicon precursor is provided to the reaction chamber. Exemplary silicon precursors can be selected from the group consisting of one or more of a silane, a halogensilane, an organosilane, and a silazane. By way of particular examples, the silicon precursor can include one or more of tris(dimethylamino)silane, bis(tert-butylamino)silane, di(sec-butylamino)silane, trisilylamine, neopentasilane, bis(dimethylamino)silane, (dimethylamino)silane (DMAS), bis(diethylamino)silane (BDEAS), bis(ethylmethylamino)silane (BEMAS), tetrakis(dimethylamino)silane (TKDMAS), trimethylsilane (SiH(CH₃)₃), tetramethylsilane (Si(Ch₃)₄), silane, tetra(ethoxy)silane (TEOS, Si(OC₂H₅)₄), tris(tert-butoxy)silanol (TBOS), tris(tert-pentoxy)silanol (TPSOL), dimethyldichlorosilane (Si(OC₂H₅)₄, Si(CH₃)₂(OCH₃)₂), and harosilane such as Sil₄, HSil₃, H₂Sil₂, H₃Sil, Si₂l₆, HSi₂l₅, H₂Si₂l₄, H₃Si₂l₃, H₄Si₂l₂, H₅Si₂l, Si₃l₈, HSiCl₃, H₂SiCl₂, H₃SiCl, H₂Si₂Cl₄, H₄Si₂Cl₂, SiCl₄, HSiCl₃, and H₂SiCl₂. A precursor with a carrier gas flow rate may be in a range of about 500 sccm to about 5000 sccm. The gas comprising the carrier gas and the precursor gas can comprise about 5 to about 10 volumetric percent of the precursor gas.

Exemplary silicon precursor flow rates during step substep 110 can be about 1 sccm to about 500 sccm or about 3 sccm to about 100 sccm. A pulse time for silicon precursor flow during step 104/substep 110 can be about 0.1 second to about 10 seconds or about 0.2 second to about 3 seconds.

During substep 112, a nitrogen reactant is provided to the reaction chamber for a nitrogen reactant pulse period. Exemplary nitrogen reactants include nitrogen and optionally oxygen or fluorine. In accordance with examples of the disclosure, the nitrogen reactant does not include hydrogen. By way of particular example, the nitrogen reactant can include one or more of nitrogen (N₂), N₂O, NO, NF₃. A nitrogen reactant gas flowrate can be in a range of about 100 to about 10000 sccm. A duration of the nitrogen reactant pulse period can range from about 0.05 second to about 5 seconds.

During substep 114, a deposition plasma power to form a plasma within the reaction chamber for a deposition plasma pulse period is applied (e.g., between conductive plates within the reaction chamber). In accordance with examples of these embodiments, a frequency of the deposition plasma power can be between about 13 MHz and about 14 MHz or about 26 MHz and about 28 MHz. A duration of the first plasma power period can be between about 1 seconds and about 30 seconds. A power for the plasma during substep 114 can be, for example, between about 100 W and about 1000 W or between about 400 W and about 800 W.

Intermediate treatment step 106 includes providing a hydrogen reactant to the reaction chamber for a hydrogen reactant pulse period (substep 116), providing a nitrogen reactant to the reaction chamber for a nitrogen reactant pulse period (substep 118), and providing a first treatment plasma power to the reaction chamber for a first treatment plasma pulse period (substep 120). The pressure and/or temperature during step 106 can be within the ranges set forth above in connection with step 102.

During substep 116, a hydrogen reactant is provided to the reaction chamber for a hydrogen reactant pulse period. Nitrogen reactant pulse period (substep 112) and the hydrogen reactant pulse period overlap for an overlap period. During the overlap period, a volumetric flow ratio of the hydrogen reactant to the nitrogen reactant is between about 0.0003:1 and about 0.1:1 to provide desired quality of the deposited silicon nitride layer. Exemplary hydrogen reactants include hydrogen and, in some cases, nitrogen. Particular exemplary hydrogen reactants can include one or more of hydrogen (H₂), NH₃, N₂H₄, and N₂H₂.

Substep 118 can be a continuation of substep 112. The nitrogen reactant and flowrate of the nitrogen reactant can be as described above.

Substep 120 includes providing a first treatment plasma power to the reaction chamber for a first treatment plasma pulse period during the overlap period (i.e., when both the hydrogen reactant and the nitrogen reactant are provided to the reaction chamber). A frequency of the plasma power applied during substep 120 can be the same as the plasma power applied during substep 114. A power for the plasma during substep 120 can be, for example, between about 100 W and about 1000 W or between about 400 W and about 800 W. A duration of the first treatment plasma pulse period can be between about 1 seconds and about 30 seconds.

During step 108, a second treatment step is performed on the deposited silicon nitride. Step 108 includes providing a nitrogen reactant to the reaction chamber (substep 122) and providing a second treatment plasma power to the reaction chamber for a second treatment plasma pulse period (substep 124).

Substep 122 can be a continuation of substep 112 and/or substep 118. The nitrogen reactant and flowrate of the nitrogen reactant can be as described above.

During substep 124, a second treatment plasma power is provided to the reaction chamber for a second treatment plasma pulse period. In accordance with examples of the disclosure, and as further illustrated below, in accordance with examples of the disclosure, the hydrogen reactant pulse period and the second treatment plasma pulse period do not overlap. In accordance with examples of the disclosure, the frequency of the second treatment plasma power can be the same or similar to the frequency of the power provided during substep 114 and/or 120. In accordance with further examples, the deposition plasma power is greater than the second treatment plasma power. The first treatment plasma power can be greater than or equal to the second treatment plasma power. A power for the plasma during substep 124 can be, for example, between about 100 W and about 1000 W or between about 400 W and about 800 W. A duration of the second treatment plasma pulse period can be between about 1 seconds and about 30 seconds.

Steps 104-108 can be considered a deposition cycle, which can be repeated one or more times. For example, steps 104-108 can be repeated a number of times until a gap on a surface of a substrate is filled with the silicon nitride and/or a desired film thickness is obtained. Further, any of steps 104-110 can be repeated prior to proceeding to the next step.

Two or more substeps of method 100 can be performed at the same time or may overlap—at least partially—in time. For example, substeps 112, 114 may overlap or be performed at the same time. Further, as illustrated in more detail below, one or more substeps— e.g., the substep of providing the nitrogen reactant, can be performed continuously during one or more other steps, during all steps, and/or during one or more deposition cycles.

Further, unless otherwise noted, steps of method 100 can be performed in any order. For example, step 108 can be performed before step 104.

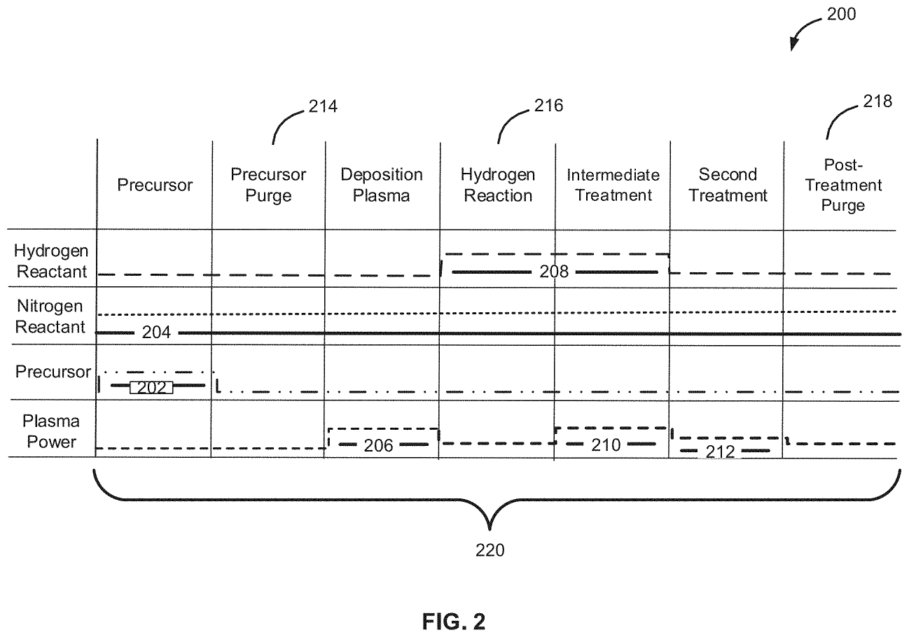

FIG. 2 illustrates a timing sequence 200 of a method, such as method 100, for depositing a silicon nitride layer. As used herein, pulse period means a period in which a gas (e.g., precursor, reactant, inert gas, and/or carrier gas) is flowed to a reaction chamber and/or a period in which power is provided (e.g., power provided to a reaction chamber to produce a plasma). A height and/or width of the illustrated pulse period is not necessarily indicative of a particular amount or duration of a pulse.

Timing sequence 200 includes a silicon precursor pulse period 202, a nitrogen reactant pulse period 204, a deposition plasma pulse period 206, a hydrogen reactant pulse period 208, a first or intermediate treatment plasma pulse period 210, and a second treatment plasma pulse period 212. Timing sequence 200 also includes a source purge period 214, a deposition purge period 216, and a post-treatment purge period 218.

Silicon precursor pulse period 202 can be the same or similar to substep 110. Nitrogen reactant pulse period 204 can include, for example, substeps 112, 118, and 122. As illustrated, nitrogen reactant pulse period 204 can be continuous through one or more deposition cycles 220. Deposition plasma pulse period 206 can be or include substep 114. Hydrogen reactant pulse period 208 can be or include substep 116. As illustrated, hydrogen reactant pulse period 208 can begin prior to first treatment plasma pulse period 210 and/or end substantially coincident with first treatment plasma pulse period 210. As further illustrated, in accordance with examples of the disclosure, hydrogen reactant pulse period 208 can end prior to a second treatment plasma pulse period 212. First treatment plasma pulse period 210 can be the same or similar to substep 120. As illustrated, first treatment plasma pulse period 210 overlaps with nitrogen reactant pulse period 204 and hydrogen reactant pulse period 208. Second treatment plasma pulse period 212 can be the same or similar to substep 124. As illustrated, second treatment plasma pulse period 212 can overlap with nitrogen reactant pulse period 204 and not overlap with silicon precursor pulse period 202, deposition plasma pulse period 206, hydrogen reactant pulse period 208, and/or first treatment plasma pulse period 210.

During source purge period 214, a carrier gas (e.g., used to provide a silicon precursor during silicon precursor pulse period 202) and/or a nitrogen reactant can be provided to the reaction chamber to facilitate distribution and/or removal of some of the silicon precursor provided during silicon precursor pulse period 202 and/or byproducts thereof. During deposition purge period 216, the carrier gas and/or the nitrogen reactant can be provided to the reaction chamber. Similarly, during post-treatment purge period 218, the carrier gas and/or the nitrogen reactant can be provided to the reaction chamber.

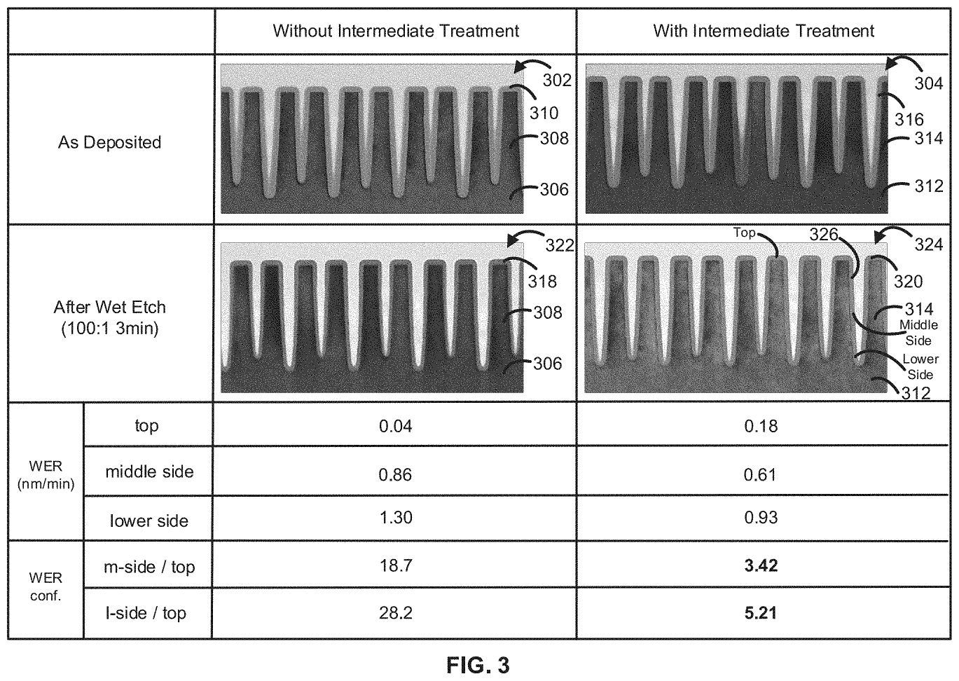

FIG. 3 illustrates scanning transmission electron microscopy (STEM) images of structures 302 and 304, 322, and 324. Structure 302 includes a substrate 306, having features 308 formed thereon. A silicon nitride layer 310 is formed overlying substrate 306 and features 308. Structure 302 was formed in accordance with method 100/timing sequence 200, but without intermediate treatment step 106. Structure 304 includes a substrate 312, having features 314 formed thereon. A silicon nitride layer 316 is formed overlying substrate 312 and features 314. Structure 304 was formed in accordance with method 100/timing sequence 200, including intermediate treatment step 106. Structure 322 illustrates structure 302 after exposure to an etch process (e.g., a dilute 100:1 hydrofluoric acid (HF) etch). As illustrated, a portion of silicon nitride layer 310 is removed, with silicon nitride layer 318 remaining after the etch process. Structure 324 illustrates structure 304 after exposure to the etch process. A portion of silicon nitride layer 316 is removed, with silicon nitride layer 320 remaining after the etch process. Silicon nitride layers 320 exhibited better quality—e.g., lower and more consistent etch rates at various locations (e.g., top, middle side, and lower side) of the silicon nitride layer 320 along sidewall 326, as set forth in the data of FIG. 3. In accordance with examples of the disclosure, the silicon nitride layer formed according to method 100/sequence 200 exhibited superior uniformity of film quality. For example, a ratio of a wet etch rate of the silicon nitride at a middle sidewall surface within the recess to a wet etch rate of the silicon nitride on the top surface of the substrate is less than 15, less than 10, or less than 5 and/or a ratio of a wet etch rate of the silicon nitride at a lower sidewall surface within the recess to a wet etch rate of the silicon nitride on the top surface of the substrate is less than 15, less than 10, or less than 6.

Turning now to FIG. 4, a reactor system 400 in accordance with exemplary embodiments of the disclosure is illustrated. Reactor system 400 can be used to perform one or more steps or substeps as described herein and/or to form one or more device structures or portions thereof as described herein.

Reactor system 400 includes a pair of electrically conductive flat-plate electrodes 414, 418 in parallel and facing each other in an interior 401 (reaction zone) of a reaction chamber 402. Although illustrated with one reaction chamber 402, system 400 can include two or more reaction chambers. A plasma can be excited within reaction chamber 402 by applying, for example, RF power from plasma power source(s) 408 to one electrode (e.g., electrode 418) and electrically grounding the other electrode (e.g., electrode 414). A temperature regulator 403 can be provided in a lower stage 414 (the lower electrode), and a temperature of a substrate 422 placed thereon can be kept at a desired temperature, such as the temperatures noted above. Electrode 418 can serve as a gas distribution device, such as a shower plate or showerhead. Precursor gases, reactant gases, and a carrier or inert gas, and the like can be introduced into reaction chamber 402 using one or more gas lines (e.g., reactant gas line 404 coupled to a reactant source 430 (e.g., a nitrogen reactant source and/or a hydrogen reactant source) and precursor gas line 406 coupled to a silicon precursor source 431 and an inert gas source 434. For example, one or more reactants (e.g., as described above) can be introduced into reaction chamber 402 using gas line 404 and/or a precursor and a carrier gas (e.g., as described above) can be introduced into the reaction chamber using gas line 406. Although illustrated with two inlet gas lines 404, 406, reactor system 400 can include any suitable number of gas lines. A flow control system, including flow controllers 432, 433, 435, can be used to control the flow of one or more reactants, precursors, and inert gases into reaction chamber 402.

In reaction chamber 402, a circular duct 420 with an exhaust line 421 can be provided, through which gas in the interior 401 of the reaction chamber 402 can be exhausted to an exhaust source 410. Additionally, a transfer chamber 423 can be provided with a seal gas line 429 to introduce seal gas into the interior 401 of reaction chamber 402 via the interior (transfer zone) of transfer chamber 423, wherein a separation plate 425 for separating the reaction zone 401 and the transfer chamber 423 can be provided (a gate valve through which a substrate is transferred into or from transfer chamber 423 is omitted from this figure). Transfer chamber 423 can also be provided with an exhaust line 427 coupled to an exhaust source 410. In some embodiments, continuous flow of a carrier gas to reaction chamber 402 can be accomplished using a flow-pass system (FPS).

Reactor system 400 can include one or more controller(s) 412 programmed or otherwise configured to cause one or more method steps as described herein to be conducted. Controller(s) 412 are coupled with the various power sources, heating systems, pumps, robotics and gas flow controllers, or valves of the reactor, as will be appreciated by the skilled artisan. By way of example, controller 412 can be configured to control gas flow of a precursor, one or more reactants, and optionally an inert gas into at least one of the one or more reaction chambers to form a layer on a surface of a substrate. Controller 412 can be further configured to provide power—e.g., within reaction chamber 402. Controller 412 can be similarly configured to perform additional steps as described herein. Controller 412 can be configured to control gas flow of a precursor, hydrogen reactant, and a nitrogen reactant into at least one of the one or more reaction chambers to form a silicon nitride layer overlying a substrate. By way of particular example, controller 412 is configured to control gas flow of a silicon precursor, a nitrogen reactant, and a hydrogen reactant into the reaction chamber to form a silicon nitride layer on a surface of a substrate, treat the silicon nitride layer using a first process comprising flowing the nitrogen reactant and the hydrogen reactant and to further treat the silicon nitride layer using a second treatment process that does not include flowing the hydrogen reactant to the reaction chamber.

Controller 412 can include electronic circuitry and software to selectively operate valves, manifolds, heaters, pumps and other components included in system 400. Such circuitry and components operate to introduce precursors, reactants, and purge gases from the respective sources. Controller 412 can control timing of gas pulse sequences, temperature of the substrate and/or reaction chamber, pressure within the reaction chamber, and various other operations to provide proper operation of the system 400.

Controller 412 can include control software to electrically or pneumatically control valves to control flow of precursors, reactants, and/or purge gases into and out of the reaction chamber 402. Controller 412 can include modules, such as a software or hardware component, e.g., a FPGA or ASIC, which performs certain tasks. A module can advantageously be configured to reside on the addressable storage medium of the control system and be configured to execute one or more processes.

In some embodiments, a dual chamber reactor (two sections or compartments for processing substrates disposed close to each other) can be used, wherein a reactant gas and a noble gas can be supplied through a shared line, whereas a precursor gas is supplied through unshared lines.

During operation of system 400, substrates, such as semiconductor wafers, are transferred from, e.g., a substrate handling area 423 to the reaction zone 401. Once substrate(s) are transferred to reaction zone 401, one or more gases, such as precursors, reactants, carrier gases, and/or purge gases, are introduced into reaction chamber 402—e.g., in accordance with timing sequence 200.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements (e.g., steps) described, may become apparent to those skilled in the art from the description. Such modifications and embodiments are also intended to fall within the scope of the appended claims.

What is claimed is:

1. A method of depositing a silicon nitride layer, the method comprising the steps of:
providing a substrate within a reaction chamber;
providing a silicon precursor to the reaction chamber for a silicon precursor pulse period;
providing a nitrogen reactant to the reaction chamber for a nitrogen reactant pulse period;
providing a deposition plasma power to form a plasma within the reaction chamber for a deposition plasma pulse period;
providing a hydrogen reactant to the reaction chamber for a hydrogen reactant pulse period, wherein the nitrogen reactant pulse period and the hydrogen reactant pulse period overlap for an overlap period;
during the overlap period, providing a first treatment plasma power to the reaction chamber for a first treatment plasma pulse period; and
providing a second treatment plasma power to the reaction chamber for a second treatment plasma pulse period,
wherein the hydrogen reactant pulse period and the second treatment plasma pulse period do not overlap.

2. The method of claim 1, wherein the deposition plasma power is greater than the second treatment plasma power.

3. The method of claim 1, wherein the deposition plasma power is between about 400 W and about 1000 W.

4. The method of claim 1, wherein the second treatment plasma power is between about 100 W and about 1000 W.

5. The method of claim 1, wherein the first treatment plasma power is greater than or equal to the second treatment plasma power.

6. The method of claim 1, wherein the first treatment plasma power is between about 100 W and about 1000 W.

7. The method of claim 1, wherein the nitrogen reactant is selected from the group consisting of nitrogen (N₂), N₂O, NO, NF3.

8. The method of claim 1, wherein the hydrogen reactant is selected from the group consisting of hydrogen (H₂), NH₃, N₂H₄, N₂H₂.

9. The method of claim 1, wherein the nitrogen reactant is continuously supplied to the reaction chamber during one or more deposition cycles.

10. The method of claim 1, wherein a volumetric flow ratio of the hydrogen reactant to the nitrogen reactant during the overlap period is between about 0.0003:1 and about 0.1:1.

11. The method of claim 1, wherein a substrate temperature during the method is between about 25° C. and about 700° C., about 50° C. to about 600° C., about 100° C. to about 500° C., about 200° C. to about 400° C., or about 300° C. to about 400° C.

12. The method of claim 1, wherein a pressure within the reaction chamber during the method is between 0.01 torr to about 50 torr or about 0.1 torr to about 30 torr.

13. The method of claim 1, wherein the silicon precursor comprises one or more of a silane, a halogensilane, an organosilane, and a silazane.

14. The method of claim 1, wherein the silicon precursor comprises one or more of tris(dimethylamino)silane, bis(tert-butylamino)silane, di(sec-butylamino)silane, trisilylamine, neopentasilane, bis(dimethylamino)silane, (dimethylamino)silane(DMAS), bis(diethylamino)silane (BDEAS), bis(ethylmethylamino)silane (BEMAS), tetrakis(dimethylamino)silane (TKDMAS), trimethylsilane (SiH(CH3)3), tetramethylsilane (Si(Ch3)4), silane, tetra(ethoxy)silane (TEOS, Si(OC2H5)4), tris(tert-butoxy)silanol (TBOS), tris(tert-pentoxy)silanol (TPSOL), dimethyldichlorosilane (Si(OC2H5)4, Si(CH3)2(OCH3)2), and harosilane such as Sil4, HSil3, H2Sil2, H3Sil, Si2l6, HSi2l5, H2Si2l4, H3Si2l3, H4si2l2, H5Si2l, Si3l8, HSiCl3, H2SiCl2, H3SiCl, H2Si2Cl4, H4Si2Cl2, SiCl4, HSiCl3, H2SiCl2.

15. The method of claim 1, wherein the silicon nitride is deposited onto sidewalls of one or more recesses on a surface of the substrate.

16. The method of claim 15, wherein a ratio of a wet etch rate of the silicon nitride at a middle sidewall surface within the recess to a wet etch rate of the silicon nitride on the top surface of the substrate is less than 15, less than 10, or less than 5.

17. A structure formed using the method of claim 1.

18. A system comprising:
a reaction chamber;
a silicon precursor source;
a nitrogen reactant source;
a hydrogen reactant source;
a plasma power source;
an exhaust source; and
a controller,
wherein the controller is configured to control gas flow of a silicon precursor, a nitrogen reactant, and a hydrogen reactant into the reaction chamber to form a silicon nitride layer on a surface of a substrate, treat the silicon nitride layer using a first process comprising flowing the nitrogen reactant and the hydrogen reactant and to further treat the silicon nitride layer using a second treatment process that does not include flowing the hydrogen reactant to the reaction chamber.
